(19) United States
(12) Patent Application Publication
(10) Pub. No.: US 2008/0012034 A1
(43) Pub. Date: Jan. 17, 2008

(54) LED PACKAGE WITH CONVERGING EXTRACTOR

(75) Inventors: James A. Thielen, Shoreview, MN (US); Catherine A. Leatherdale, Woodbury, MN (US); Andrew J. Ouderkirk, Woodbury, MN (US); Dong Lu, Woodbury, MN (US); Amy S. Barnes, St. Paul, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 11/778,385

(22) Filed: Jul. 16, 2007

Related U.S. Application Data
(60) Provisional application No. 60/807,565, filed on Jul. 17, 2006.

(51) Int. Cl. H01L 33/00

(52) U.S. Cl. 257/98

(57) ABSTRACT

In one aspect, the present application discloses a light source comprising an LED die optically coupled to an extractor comprising a plurality of optical elements each having a base, an apex smaller than the base, and a converging side extending between the base and the apex. The extractor base is no greater in size than the emitting surface of the LED die. In another aspect, methods of making light sources are disclosed, comprising the steps of providing an LED die having an emitting surface; forming a plurality of optical elements each having a base, an apex smaller than the base, and a converging side extending between the base and the apex; arranging the plurality of optical elements to form an extractor, the extractor having an extractor base no greater in size than the emitting surface; and optically coupling the extractor base to the emitting surface of the LED die.

### CROSS-REFERENCE TO RELATED APPLICATIONS

This application claims the benefit of U.S. Provisional Application No. 60/807,565 (Attorney Docket No. 62168US002), filed on Jul. 17, 2006, which is incorporated herein by reference in its entirety.

### FIELD OF INVENTION

The present invention relates to light sources. More particularly, the present invention relates to light sources in which light emitted from a light emitting diode (LED) is extracted using optical elements.

### BACKGROUND

LEDs have the inherent potential to provide the brightness, output, and operational lifetime that would compete with conventional light sources. Unfortunately, LEDs produce light in semiconductor materials, which have a high refractive index, thus making it difficult to efficiently extract light from the LED without substantially reducing brightness. Because of a large refractive index mismatch between the semiconductor and air, an angle of an escape cone for the semiconductor-air interface is relatively small. Much of the light generated in the semiconductor is totally internally reflected and cannot escape the semiconductor, thus reducing brightness.

Previous approaches of extracting light from LED dies have used epoxy or silicone encapsulants, in various shapes, e.g., a conformal domed structure over the LED die or formed within a reflector cup shaped around the LED die. Encapsulants have a higher index of refraction than air, which reduces the total internal reflection at the semiconductor-encapsulant interface, thus enhancing extraction efficiency. Even with encapsulants, however, there still exists a significant refractive index mismatch between a semiconductor die (typical index of refraction, n of 2.5 or higher) and an epoxy encapsulant (typical n of 1.5).

Recently, it has been proposed to make an optical element separately and then bring it into contact or close proximity with a surface of an LED die to couple or “extract” light from the LED die. Such an element can be referred to as an extractor. Examples of such optical elements are described in U.S. Pat. No. 7,064,355, titled LIGHT EMITTING DIODES WITH IMPROVED LIGHT EXTRACTION EFFICIENCY (Camras et al.).

### SUMMARY

In one aspect, the present disclosure provides a light source that includes an LED die having an emitting surface, and an extractor. The extractor includes a plurality of optical elements each having a base, an apex smaller than the base, and a converging side extending between the base and the apex. The extractor has an extractor base no greater in size than the emitting surface. The extractor base is optically coupled to the emitting surface forming an interface between the extractor and the LED die.

In another aspect, the present disclosure provides a method of making a light source that includes providing an LED die having an emitting surface; and forming a plurality of optical elements each having a base, an apex smaller than the base, and a converging side extending between the base and the apex. The method further includes arranging the plurality of optical elements to form an extractor having an extractor base no greater in size than the emitting surface; and optically coupling the extractor base to the emitting surface of the LED die.

In another aspect, the present disclosure provides a light source that includes an LED die having an emitting surface, and an extractor. The extractor includes a plurality of optical elements each having a base, an apex smaller than the base, and a converging side extending between the base and the apex. The light source further includes an encapsulant material encapsulating the LED die and the extractor. The extractor includes open portions for providing electrical contacts for the LED die. The extractor has an extractor base no greater in size than the emitting surface, where the extractor base is optically coupled to the emitting surface forming an interface between the extractor and the LED die. And the extractor is bonded to the LED die at the emitting surface. The light source emits light in a side emitting pattern, where more than 50 percent of the emitted light is emitted at a polar angle greater than or equal to 45°.

The above summary is not intended to describe each disclosed embodiment or every implementation of the present invention. The figures and the detailed description below more particularly exemplify illustrative embodiments.

### BRIEF DESCRIPTION OF THE DRAWINGS

The invention may be more completely understood in consideration of the following detailed description of various embodiments of the invention in connection with the accompanying drawings, where like reference numerals designate like elements. The appended drawings are intended to be illustrative examples and are not intended to be limiting. Sizes of various elements in the drawings are approximate and may not be to scale.

FIG. 1 is a schematic side view illustrating an optical element and LED die configuration in one embodiment.

FIGS. 2a-c are schematic perspective views of optical elements according to additional embodiments.

FIG. 3 is a schematic perspective view of an optical element according to another embodiment.

FIGS. 4a-4i are schematic top views of optical elements according to several alternative embodiments.

FIG. 5a-c are schematic front views illustrating optical elements in alternative embodiments.

FIGS. 6a-e are schematic side views of optical elements and LED dies according to alternative embodiments.

FIG. 7a is a schematic perspective view of an extractor and an LED die according to one embodiment.

FIG. 7b is a schematic side view of the extractor of FIG. 7a.

FIGS. 8a-d are schematic bottom views of extractors and LED dies according to several embodiments.

FIGS. 9a-g are schematic perspective views of alternative embodiments of extractors.

FIGS. 10a-c are schematic top views of additional embodiments of extractors.

FIG. 11 is a schematic partial view of an extractor and an LED die according to another embodiment.

FIG. 12a shows an intensity contour plot as described in Example 1.

FIG. 12b shows an intensity line plot as described in Example 1.

FIG. 12c shows the arrangement of LED die used in Example 1.

FIG. 13a shows an intensity contour plot as described in Example 2.

FIG. 13b shows an intensity line plot as described in Example 2.

FIG. 13c shows the arrangement of LED die and optical element used in Example 2.

FIG. 14a shows an intensity contour plot as described in Example 3.

FIG. 14b shows an intensity line plot as described in Example 3.

FIG. 14c shows the arrangement of LED die and extractor used in Example 3.

### DETAILED DESCRIPTION

Recently, it has been proposed to make optical elements to more efficiently “extract” light from an LED die. Extracting optical elements are made separately and then brought into contact or close proximity with a surface of the LED die. Such optical elements can be referred to as extractors. Most of the applications utilizing optical elements such as these have shaped the optical elements to extract the light out of the LED die and to emit it in a generally forward direction. Some shapes of optical elements can also collimate light. These are known as “optical concentrators.” See e.g., U.S. Pat. No. 7,064,355 LIGHT EMITTING DIODES WITH IMPROVED LIGHT EXTRACTION EFFICIENCY (Camras et al.); U.S. Patent Application Pub. No. 2006/0091411, HIGH BRIGHTNESS LED PACKAGE (Attorney Docket No. 60217US002); and U.S. Patent Application Pub. No. 2006/0091784, titled LED PACKAGE WITH NON-BONDED OPTICAL ELEMENT (Attorney Docket No. 60216US002).

Side emitting optical elements have also been proposed. See U.S. Pat. No. 7,009,213 titled LIGHT EMITTING DEVICES WITH IMPROVED LIGHT EXTRACTION EFFICIENCY (Camras et al.). The side-emitting optical elements described in U.S. Pat. No. 7,009,213 rely on mirrors to redirect the light to the sides.

The present application discloses optical elements shaped to redirect light to the sides without the need for mirrors or other reflective layers. Applicants found that particular shapes of optical elements can be useful in redirecting the light to the sides due to their shape, thus eliminating the need for additional reflective layers or mirrors. Such optical elements generally have at least one converging side, as described below. The converging side serves as a reflective surface for light incident at high angles because light is totally internally reflected at the interface of the optical element (preferably high refractive index) and the surrounding medium (e.g., air, lower refractive index).

Eliminating mirrors improves the manufacturing process and reduces costs. Optical elements having converging shapes also use less material, thus providing additional cost savings, since materials used for optical elements can be very expensive. Further cost savings can be realized when groups of optical elements are optically coupled to a single LED die. In such embodiments, even less material is used because each individual optical element in the group can be made smaller while maintaining the same aspect ratio (height to base ratio) as a larger, single optical element having the same shape. Applicants unexpectedly found that groups of such optical elements still provide relatively good extraction efficiency (compared to a single optical element on a single LED die). Additional advantages of using groups, clusters, or arrays of optical elements on a single LED die include the option to leave at least a portion of one or more of the optical elements out thus exposing a portion of the LED die where electrical contacts can be provided.

From a manufacturing perspective, fabrication of a plurality of structures on a single base instead of one tall structure offers several advantages. In the case of an array of pyramid-shaped optical elements, by decreasing the size of the base of each individual pyramid, the height of the pyramid array can be reduced while still maintaining the same aspect ratio of base to height for each individual pyramid. This decrease in overall extractor height allows for greater versatility when fabricating the parts through a viscous flow process. For viscous flow formation, the temperature should remain above the softening point of the glass to maintain sufficient flow properties. The taller the structure, the greater the distance that the material must travel before it can drop below this critical temperature. Additionally, precision machining of deep structures may require multiple passes by a diamond turning machine or significantly greater fabrication time by methods such as sinker electrical discharge machining (EDM). By using an array of smaller optical elements, some of these problems can be avoided. Finally, the material cost for an array of optical elements may be significantly lower than the cost for a single optical element having the same aspect ratio and similar extraction efficiency. Similar benefits can apply to a group or cluster of optical elements arranged to form an extractor.

The present application discloses light sources having extractors for efficiently extracting light out of LED dies and for optionally modifying the angular distribution of the emitted light. An extractor is optically coupled to the emitting surface of an LED die (or LED die array) to efficiently extract light. Optionally, the extractor also modifies the emission pattern of the emitted light. LED sources that include such extractors can be useful in a variety of applications, including without limitation backlights in liquid crystal displays or backlit signs, and general lighting applications.

Light sources comprising groups of converging optical elements described herein can be suited for use in backlights, both edge-lit and direct-lit constructions. Wedge-shaped optical elements are particularly suited for edge-lit backlights, where the light source is disposed along an outer portion of the backlight. Pyramid or cone-shaped converging optical elements can be particularly suited for use in direct-lit backlights. Such light sources can be used as single light source elements, or can be arranged in a group, cluster, or array, depending on the particular backlight design.

For a direct-lit backlight, the light sources are generally disposed between a diffuse or specular reflector and an upper film stack that can include prism films, diffusers, and reflective polarizers. These can be used to direct the light emitted from the light source towards the viewer with the most useful range of viewing angles and with uniform brightness. Exemplary prism films include brightness enhancement films such as BEF available from 3M Company, St. Paul, Minn. Exemplary reflective polarizers include DBEF also available from 3M Company, St. Paul, Minn. For an edge-lit backlight, the light source can be positioned to inject light into a hollow or solid light guide. The light guide generally has a reflector below it and an upper film stack as described above.

For simplicity, some of the following details are described in terms of a single optical element. Unless specified otherwise, the characteristics of a single optical element also apply to groups, clusters, and arrays of such elements.

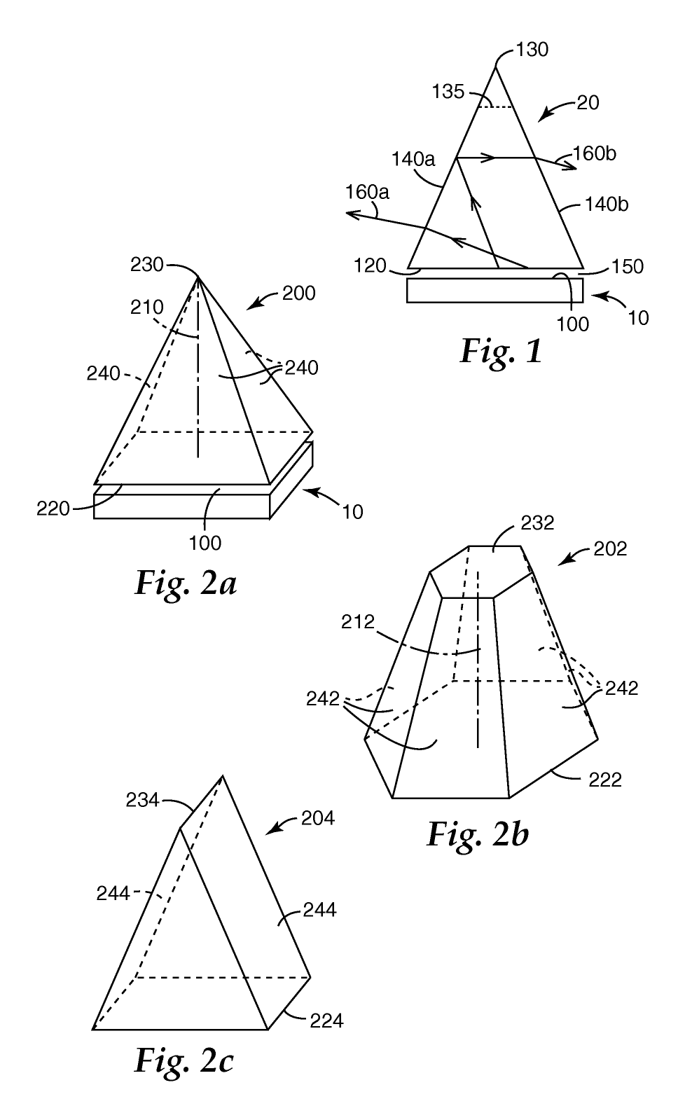

FIG. 1 is a schematic side view illustrating a light source according to one embodiment. The light source comprises an optical element 20 and an LED die 10. The optical element 20 has a triangular cross-section with a base 120 and two converging sides 140a-b joined opposite the base 120 to form an apex 130. The apex can be a point, as shown at 130 in FIG. 1, or can be blunted, as for example in a truncated triangle (shown by dotted line 135). A blunted apex can be flat, rounded, or a combination thereof. The apex is smaller than the base and preferably resides over the base. In some embodiments, the apex is no more than 20% of the size of the base. Preferably, the apex is no more than 10% of the size of the base. In FIG. 1, the apex 130 is centered over the base 120. However, embodiments where the apex is not centered or is skewed away from the center of the base are also contemplated.

The optical element 20 is optically coupled to the LED die 10 to extract light emitted by the LED die 10. The primary emitting surface 100 of the LED die 10 is substantially parallel and in close proximity to the base 120 of the optical element 20. Optically coupling the optical element to the LED die forms an interface between the base of the optical element and the emitting surface of the LED die. The LED die 10 and optical element 20 can be optically coupled in a number of ways including bonded and non-bonded configurations, which are described in more detail below.

The converging sides 140a-b of the optical element 20 act to modify the emission pattern of light emitted by the LED die 10, as shown by the arrows 160a-b in FIG. 1. A typical bare LED die emits light in a first emission pattern. Typically, the first emission pattern is generally forward emitting or has a substantial forward emitting component. A converging optical element, such as optical element 20 depicted in FIG. 1, modifies the first emission pattern into a second, different emission pattern. For example, a wedge-shaped optical element directs light emitted by the LED die to produce a side emitting pattern having two lobes. FIG. 1 shows exemplary light rays 160a-b emitted by the LED die entering the optical element 20 at the base. A light ray emitted in a direction forming a relatively low incidence angle with the converging side 140a will be refracted as it exits the high index material of the optical element 20 into the surrounding medium (e.g., air). Exemplary light ray 160a shows one such light ray, incident at a small angle with respect to normal. A different light ray, emitted at a high incidence angle, an angle greater than or equal to the critical angle, will be totally internally reflected at the first converging side it encounters (140a). However, in a converging optical element such as the one illustrated in FIG. 1, the reflected ray will subsequently encounter the second converging side (140b) at a low incidence angle, where it will be refracted and allowed to exit the optical element. An exemplary light ray 160b illustrates one such light path.

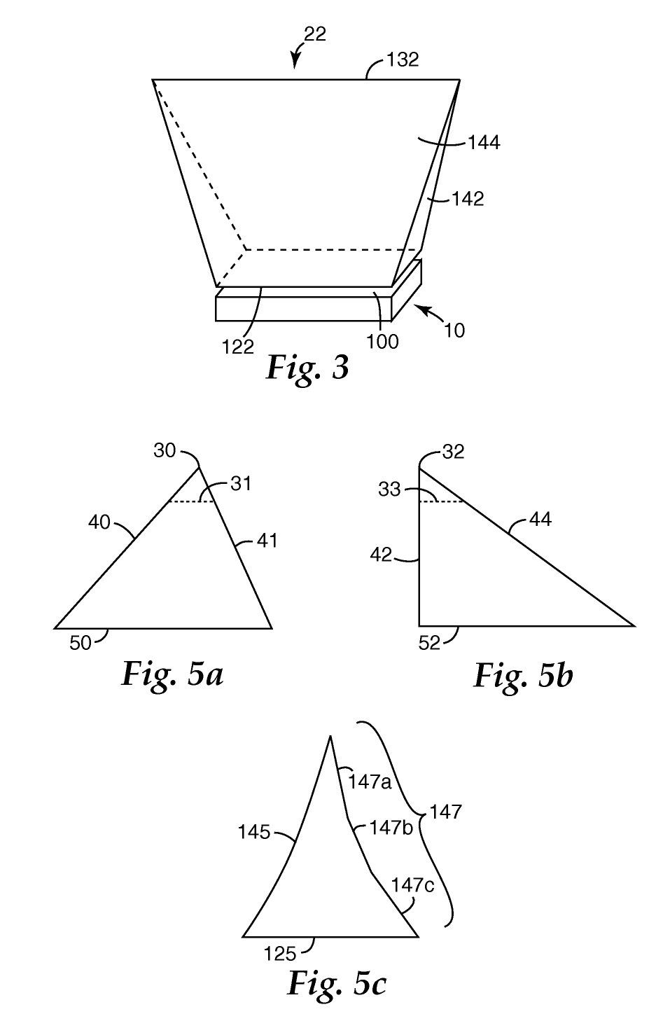

An optical element or a group of optical elements having at least one converging side can modify a first light emission pattern into a second, different light emission pattern. For example, a generally forward emitting light pattern can be modified into a second, generally side-emitting light pattern with such converging optical elements. In other words, a high index optical element or extractor comprising a plurality of optical elements can be shaped to direct light emitted by the LED die to produce a side emitting pattern. If the optical element or extractor is rotationally symmetric (e.g., optical element shaped as a cone) the resulting light emission pattern will have a torroidal distribution—the intensity of the emitted light will be concentrated in a circular pattern around the optical element. If, for example, an optical element is shaped as a wedge (see FIG. 3) the side emitting pattern will have two lobes. For example, the intensity contour plot will show the light intensity concentrated in two zones. In case of a symmetric wedge, the two lobes will be located on opposing sides of the optical element (two opposing zones). For optical elements having a plurality of converging sides, the side emitting pattern will typically have a corresponding plurality of lobes. For example, for an optical element shaped as a four-sided pyramid, the resulting side emitting pattern will have four lobes. The side emitting pattern can be symmetric or asymmetric. An asymmetric pattern will be produced when the apex of the optical element is placed asymmetrically with respect to the base or emission surface. Those skilled in the art will appreciate the various permutations of such arrangements and shapes to produce a variety of different emission patterns, as desired.

In some embodiments, the side emitting pattern has an intensity distribution with a maximum at a polar angle of at least 30°. Preferably, the side emitting pattern has a maximum intensity at a polar angle ≧45°. In other embodiments the side emitting pattern has an intensity distribution centered at a polar angle of at least 30°. Preferably, the side emitting pattern has an average intensity at a polar angle ≧45°. Other intensity distributions are also possible with presently disclosed optical elements, including, for example those having maximum and/or average intensities at 30°, 45°, or 60° polar angle. In some embodiments, the light source emits light in a side emitting pattern wherein more than 50% of the emitted light is emitted at a polar angle ≧45°.

Extractors disclosed herein include a plurality of optical elements arranged in a group, cluster, or array. In some embodiments, all the optical elements are similarly shaped. In other embodiments, the plurality of optical elements includes two or more different shapes of optical elements. Some of the optical elements can be converging, while others are not. The particular arrangement and shape of the optical elements will be guided by the desired optical characteristics of the final light distribution or a particular end use application. The optical elements can be arranged in a variety of ways, including without limitation symmetrically, asymmetrically, regularly, irregularly, randomly, in clusters, or combinations thereof.

Converging optical elements can have a variety of forms. Each optical element has a base, an apex, and at least one converging side. The base can have any shape (e.g., square, circular, symmetrical or non-symmetrical, regular or irregular). The apex can be a point, a line, or a surface (in case of a blunted apex). Regardless of the particular converging shape, the apex is smaller in surface area than the base, so that the side(s) converge from the base towards the apex. A converging optical element can be shaped as a pyramid, a cone, a wedge, or a combination thereof. Each of these shapes can also be truncated near the apex, forming a blunted apex. A converging optical element can have a polyhedral shape, with a polygonal base and at least two converging sides. For example, a pyramid or wedge-shaped optical element can have a rectangular or square base and four sides wherein at least two of the sides are converging sides. The other sides can be parallel sides, or alternatively can be diverging or converging. The shape of the base need not be symmetrical and can be shaped, for example, as a trapezoid, parallelogram, quadrilateral, or other polygon. In other embodiments, a converging optical element can have a circular, elliptical, or an irregularly-shaped but continuous base. In these embodiments, the optical element can be said to have a single converging side. For example, an optical element having a circular base can be shaped as a cone. Generally, a converging optical element comprises a base, an apex residing (at least partially) over the base, and one or more converging sides joining the apex and the base to complete the solid.

FIG. 2a shows one embodiment of a converging optical element 200 shaped as a four-sided pyramid having a base 220, an apex 230, and four sides 240. In this particular embodiment, the base 220 can be rectangular or square and the apex 230 is centered over the base (a projection of the apex in a line 210 perpendicular to the plane of the base is centered over the base 220). FIG. 2a also shows an LED die 10 having an emitting surface 100 which is proximate and parallel to the base 220 of the optical element 200. The LED die 10 and optical element 200 are optically coupled at the emitting surface—base interface. Optical coupling can be achieved in several ways, described in more detail below. For example, the LED die and optical element can be bonded together. In FIG. 2a the base and the emitting surface of the LED die are shown as substantially matched in size. In other embodiments, the base can be larger or smaller than the LED die emitting surface.

FIG. 2b shows another embodiment of a converging optical element 202. Here, optical element 202 has a hexagonal base 222, a blunted apex 232, and six sides 242. The sides extend between the base and the apex and each side converges towards the apex 232. The apex 232 is blunted and forms a surface also shaped as a hexagon, but smaller than the hexagonal base.

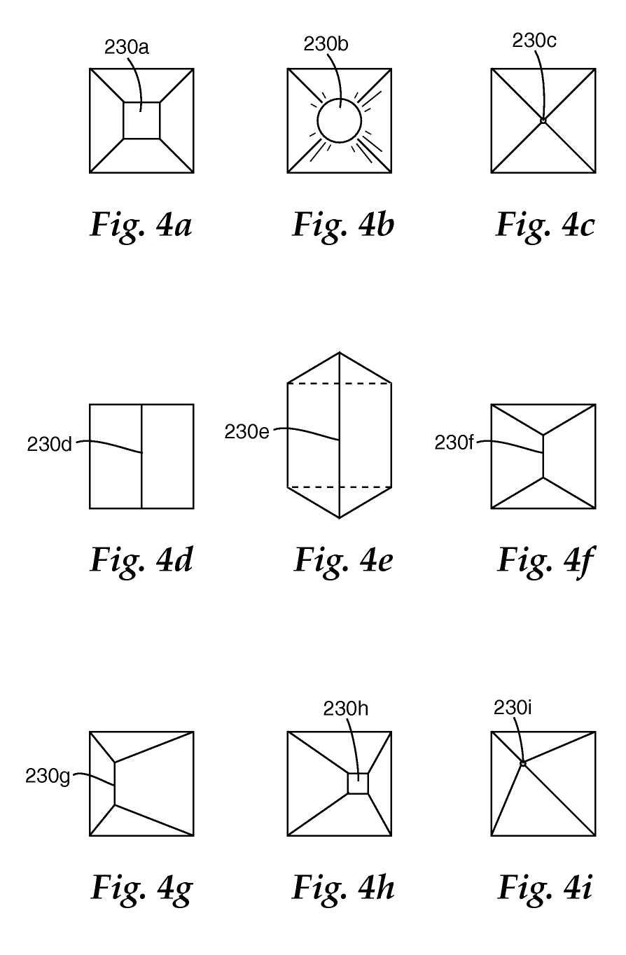

FIG. 2c shows another embodiment of an optical element 204 having two converging sides 244, a base 224, and an apex 234. In FIG. 2c, the optical element is shaped as a wedge and the apex 234 forms a line. The other two sides are shown as parallel sides. Viewed from the top, the optical element 204 is depicted in FIG. 4d.

Alternative embodiments of wedge-shaped optical elements also include shapes having a combination of converging and diverging sides, such as the optical element 22 shown in FIG. 3. In the embodiment shown in FIG. 3, the wedge-shaped optical element 22 resembles an axe-head. The two diverging sides 142 act to collimate the light emitted by the LED die. The two converging sides 144 converge at the top forming an apex 132 shaped as a line residing over the base when viewed from the side (see FIG. 1), but having portions extending beyond the base when viewed as shown in FIG. 3 (see FIG. 4e). The converging sides 144 allow the light emitted by the LED die 10 to be redirected to the sides, as shown in FIG. 1. Other embodiments include wedge shapes where all sides converge, for example as shown in FIG. 4f.

The optical element can also be shaped as a cone having a circular or elliptical base, an apex residing (at least partially) over the base, and a single converging side joining the base and the apex. As in the pyramid and wedge shapes described above, the apex can be a point, a line (straight or curved) or it can be blunted forming a surface.

FIGS. 4a-4i show top views of several alternative embodiments of an optical element. FIGS. 4a-4f show embodiments in which the apex is centered over the base. FIGS. 4g-4i show embodiments of asymmetrical optical elements in which the apex is skewed or tilted and is not centered over the base.

FIG. 4a shows a pyramid-shaped optical element having a square base, four sides, and a blunted apex 230a centered over the base. FIG. 4h shows a pyramid-shaped optical element having a square base, four sides, and a blunted apex 230h that is off-center. FIG. 4b shows an embodiment of an optical element having a square base and a blunted apex 230b shaped as a circle. In this case, the converging sides are curved such that the square base is joined with the circular apex. FIG. 4c shows a pyramid-shaped optical element having a square base, four triangular sides converging at a point to form an apex 230c, which is centered over the base. FIG. 4i shows a pyramid-shaped optical element having a square base, four triangular sides converging at a point to form an apex 230i, which is skewed (not centered) over the base.

FIGS. 4d-4g show wedge-shaped optical elements. In FIG. 4d, the apex 230d forms a line residing and centered over the base. In FIG. 4e, the apex 230e forms a line that is centered over the base and partially resides over the base. The apex 230e also has portions extending beyond the base. The top view depicted in FIG. 4e can be a top view of the optical element shown perspective in FIG. 3 and described above. FIG. 4f and FIG. 4g show two alternative embodiments of a wedge-shaped optical element having an apex forming a line and four converging sides. In FIG. 4f, the apex 230f is centered over the base, while in FIG. 4g, the apex 230g is skewed.

FIGS. 5a-5c show side views of an optical element according to alternative embodiments. FIG. 5a shows one embodiment of an optical element having a base 50 and sides 40 and 41 starting at the base 50 and converging towards an apex 30 residing over the base 50. Optionally, the sides can converge toward a blunted apex 31. FIG. 5b shows another embodiment of an optical element having a base 52, a converging side 44 and a side 42 perpendicular to the base. The two sides 42 and 44 form an apex 32 residing over the edge of the base. Optionally, the apex can be a blunted apex 33. FIG. 5c shows a side view of an alternative optical element having a generally triangular cross section. Here, the base 125 and the sides 145 and 147 generally form a triangle, but the sides 145 and 147 are non-planar surfaces. In FIG. 5c the optical element has a left side 145 that is curved and a right side that is faceted (i.e. it is a combination of three smaller flat portions 147a-c). The sides can be curved, segmented, faceted, convex, concave, or a combination thereof. Such forms of the sides still function to modify the angular emission of the light extracted similarly to the planar or flat sides described above, but offer an added degree of customization of the final light emission pattern.

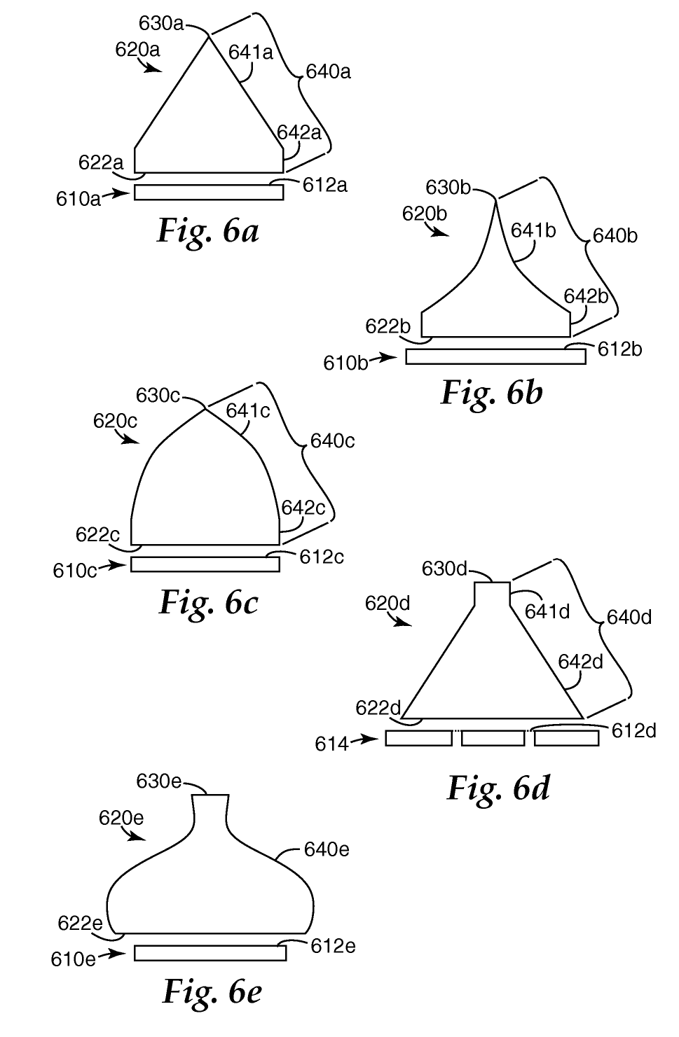

FIGS. 6a-6e depict alternative embodiments of optical elements 620a-e having non-planar sides 640a-e extending between each base 622a-e and apex 630a-e, respectively. In FIG. 6a, the optical element 620a has sides 640a comprising two faceted portions 641a and 642a. The portion 642a near the base 622a is perpendicular to the base 622a while the portion 641a converges toward the apex 630a. Similarly, in FIGS. 6b-c, the optical elements 620b-c have sides 640b-c formed by joining two portions 641b-c and 642b-c, respectively. In FIG. 6b, the converging portion 641b is concave. In FIG. 6c, the converging portion 641c is convex. FIG. 6d shows an optical element 620d having two sides 640d formed by joining portions 641d and 642d. Here, the portion 642d near the base 622d converges toward the blunted apex 630d and the top-most portion 641d is perpendicular to the surface of the blunted apex 630d. FIG. 6e shows an alternative embodiment of an optical element 620e having curved sides 640e. Here, the sides 640e are s-shaped, but generally converge towards the blunted apex 630e. When the side is formed of two or more portions, as in FIGS. 6a-6e, preferably the portions are arranged so that the side is still generally converging, even though it may have portions which are non-converging.

In one embodiment, a light source comprises an extractor having a plurality of optical elements optically coupled to a single LED die. Each optical element has a base, an apex smaller than the base, and one or more converging sides extending between the base and the apex, as described previously. The individual optical elements forming the extractor need not be identical in shape, size, or composition. For example, in one embodiment, the extractor comprises a 2×2 array of sapphire optical elements shaped as pyramids in which two of the four pyramidal elements have a ratio of height to side-of-base of 2 to 1 and two other of the four pyramidal elements have a ratio of height to side-of-base of 1.5 to 1. In another embodiment, the extractor comprises a 2×2 array of sapphire optical elements shaped as pyramids in which two of the four pyramidal elements have base dimensions of 0.5 mm by 0.5 mm and a height of 1 mm, while two other of the four pyramidal elements have base dimensions of 0.4 mm by 0.4 mm and a height of 1 mm. In yet another embodiment, the extractor comprises a 3×3 array of sapphire optical elements in which the optical element in the center of the array, i.e., the optical element of the array in the second row, second column, has a circular shaped base and the remaining 8 optical elements of the array have a square shaped base. In another embodiment, the extractor comprises a group of optical elements, wherein only some of the optical elements have one or more converging sides. In other embodiments, other combinations of differing shapes, sizes, and/or compositions are used.

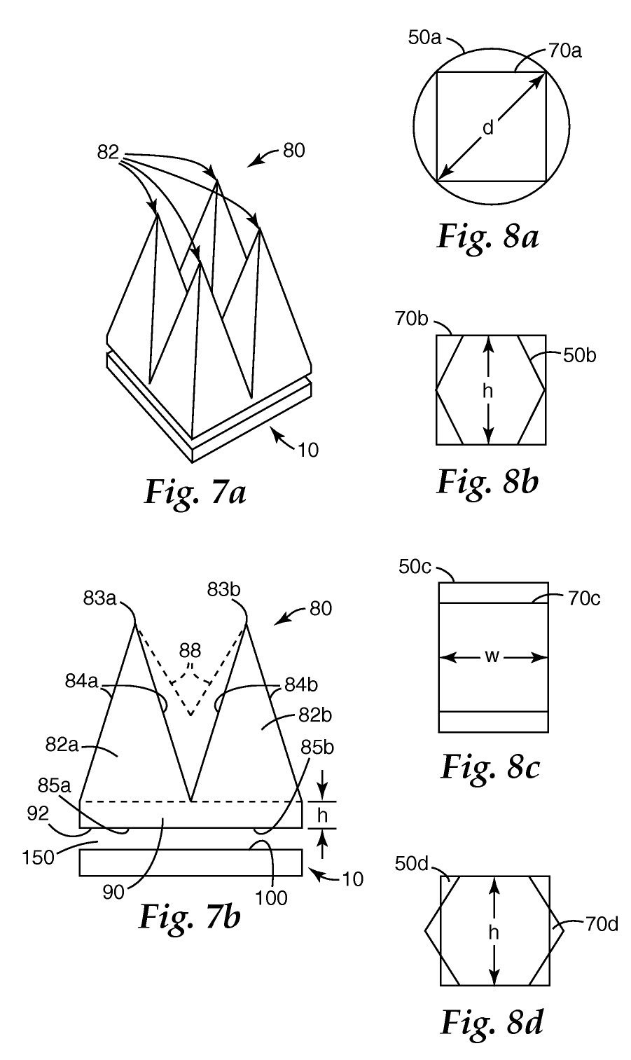

FIG. 7a is a perspective view of an exemplary extractor 80 comprising four pyramid-shaped optical elements 82. The extractor 80 is optically coupled to the LED die 10. Each optical element 82 has a base, an apex smaller than the base, and four converging sides extending between the base and the apex.

FIG. 7b shows a side view of the extractor 80. In this view two of the four optical elements 82 are visible (82a and 82b). Each optical element 82a-b has a base 85a-b, an apex 83a-b, and converging sides 84a-b joining the base and the apex. The sides of each optical element need not be symmetrical, as shown for example by the dotted line 88. Similarly, the optical elements in the array need not be identical in shape. For example, in one embodiment, the extractor comprises a 2×2 array of optical elements in which two of the four optical elements have a portion near the base that is perpendicular to the base and two other of the four optical elements have a concave converging portion. In another embodiment, the extractor comprises a 2×2 array of optical elements in which two of the four optical elements have base dimensions of 0.5 mm by 0.5 mm and a height of 1 mm, while two other of the four pyramidal optical elements have base dimensions of 0.4 mm by 0.4 mm and a height of 1 mm. In yet another embodiment, the extractor comprises a 3×3 array of sapphire optical elements in which the optical element in the center of the array, i.e., the optical element of the array in the second row, second column, optical element of the array, has a portion near the base that converges toward a blunted apex and the top-most portion is perpendicular to the surface of the blunted apex while the remaining 8 optical elements of the array have converging portions that are concave. Other combinations of differing shapes, sizes, and/or compositions are possible. Some or all of the optical elements in the array can have blunted apexes. In other embodiments, other combinations of differing shapes are used.

The extractor 80 has an extractor base 92 formed by the combination of the individual optical element bases 85a and 85b. The LED die has an emitting surface 100 which is proximate to the base of the extractor. The extractor base 92 and emitting surface 100 are typically parallel to each other, separated by a gap 150. In some embodiments, however, the extractor base 92 and emitting surface 100 can be non-parallel. For example, extractor base 92 and emitting surface 100 can be positioned such that the gap 150 is shaped as a wedge. The LED die 10 and the extractor 80 are optically coupled at the emitting surface—extractor base interface.

Extractors can be made by arranging individual prefabricated optical elements into groups. Groups of optical elements can be arranged in random patterns, regular, repeating patterns, arrays, and the like. The arrangement can be symmetric, asymmetric, regular or irregular, or any combination thereof. Optionally, one or more clusters of optical elements can be arranged to form an extractor. Preferably, extractors are formed by arranging some or all of the optical elements into an array.

Extractors can also be fabricated by forming a plurality of optical elements from a single workpiece. For example, extractors comprising arrays of optical elements can be fabricated by abrading a workpiece to form channels that define the array of optical elements. Alternatively, extractors comprising groups, clusters or arrays of optical elements can be fabricated by molding the extractor. Optionally, both molding and abrading methods can be combined.

Examples of manufacturing methods include, without limitation, using precision abrasive techniques disclosed in commonly assigned U.S. Patent Application Pub. No. 2006/0094340, titled PROCESS FOR MANUFACTURING OPTICAL AND SEMICONDUCTOR ELEMENTS, (Attorney Docket No. 60203US002), U.S. Patent Application Pub. No. 2006/0094322, titled PROCESS FOR MANUFACTURING A LIGHT EMITTING ARRAY, (Attorney Docket No. 60204US002), and U.S. patent application Ser. No. 11/288,071, titled ARRAYS OF OPTICAL ELEMENTS AND METHOD OF MANUFACTURING SAME, (Attorney Docket No. 60914US002). Alternatively, the extractor can be manufactured by using molding techniques, including for example methods disclosed in commonly assigned U.S. patent application Ser. No. 11/381,512, titled “METHODS OF MAKING LED EXTRACTOR ARRAYS” (Attorney Docket No. 62114US002). For optical elements with base sizes smaller than about 10 μm, photolithography followed by wet or dry etching processes could be used for fabrication.

Light sources can be made by providing an LED die having an emitting surface, forming a plurality of optical elements and arranging the optical elements to form an extractor, the group of optical element bases forming the extractor base (with or without open portions), and optically coupling the extractor base to the emitting surface of the LED die. In some embodiments, the extractor can be formed by molding a group of optical elements. Alternatively, the extractor can be formed by abrading a workpiece to form the plurality of optical elements. The arranging step can include grouping the optical elements into a particular arrangement (e.g., clustering some or all of the optical elements) or forming an array of optical elements. The arranging step can include placing one optical element proximate the LED die at a time or can include first forming the extractor by grouping the optical elements and subsequently placing the entire extractor proximate the LED die. Optionally, the arranging step includes leaving portions of the extractor open for providing electrical contacts for the LED die(s). In some embodiments, the forming and arranging steps can be performed simultaneously (e.g., abrading an workpiece to form an array of optical elements). The optically coupling step can include bonding the extractor base to the emitting surface of the LED die. Alternatively, the optically coupling step can include placing the extractor optically close to the emitting surface. Optionally, the optically coupling step can include adding a thin optically conducting layer between the emitting surface of the LED die and the base of the extractor.

Preferably, the size of the extractor base is matched to the size of the LED die at the emitting surface. FIGS. 8a-8d show exemplary embodiments of such arrangements. In FIG. 8a an extractor having a circular base 50a is optically coupled to an LED die having a square emitting surface 70a. Here, the base and emitting surface are matched by having the diameter “d” of the circular base 50a equal to the diagonal dimension (also “d”) of the square emitting surface 70a. In FIG. 8b, an extractor having a hexagonal base 50b is optically coupled to an LED die having a square emitting surface 70b. Here, the height “h” of the hexagonal base 50b matches the height “h” of the square emitting surface 70b. In FIG. 8c, an extractor having a rectangular base 50c is optically coupled to an LED die having a square emitting surface 70c. Here, the width “w” of both the base and the emitting surface are matched. In FIG. 8d, an extractor having a square base 50d is optically coupled to an LED die having a hexagonal emitting surface 70d. Here, the height “h” of both the extractor base and the emitting surface are matched. A simple arrangement, in which both the base and emitting surface are identically shaped and have the same surface area, also meets this criteria. The surface area of the extractor base is matched to the surface area of the emitting surface of the LED die. Other arrangements will be apparent to those skilled in the art.

In some embodiments, a light source comprises an extractor optically coupled to a group of LED dies. Such arrangements can allow for ease of manufacturing. For example, an extractor comprising a 6×6 array of optical elements can be optically coupled to a 3×3 array of LED dies. This arrangement can be particularly useful when red, green, and blue LEDs are combined in the array to produce white light when mixed.

When an extractor is coupled to an array of LED dies, the size of the LED die array at the emitting surface side can be matched to the size of the base of the extractor. Again, the shape of the LED die array need not match the shape of the extractor base. Preferably the extractor base and LED die array are matched in at least one dimension (e.g., diameter, width, height, or surface area).

Alternatively, the size of the LED die at the emitting surface or the combined size of the LED die array can be smaller or larger than the size of the extractor base. FIGS. 6a and 6c show single optical elements embodiments in which the emitting surface (612a and 612c, respectively) of the LED die (610a and 610c, respectively) is matched to the size of the base (622a and 622c, respectively). FIG. 6b shows an LED die 610b having an emitting surface 612b that is larger than the base 622b. FIG. 6d shows an array 614 of LED dies, the array having a combined size at the emitting surface 612d that is larger than the size of the base 622d. FIG. 6e shows an LED die 610e having an emitting surface 612e that is smaller than the base 622e. Similar arrangements can be used when an extractor comprising a group, cluster, or array of optical elements is used in place of a single optical element. Likewise, a group, cluster, or similar arrangement of LED dies can be used instead of an array of LED dies.

For example, in an embodiment where the LED die emitting surface is a square having 1 mm sides, the extractor base can be shaped to be a matching square having 1 mm sides. Alternatively, a square LED die emitting surface can be optically coupled to a rectangular extractor base, the rectangle having one of its sides matched in size to the size of the emitting surface side. The non-matched side of the rectangle can be larger or smaller than the side of the square. Optionally, an extractor can be made having a circular base having a diameter equal to the diagonal dimension of the emitting surface. A circular array of optical elements could be made, for example by first providing a truncated cone of material and then cutting channels into the cone, the channels forming a plurality of smaller optical elements. For example, a 1 mm by 1 mm square emitting surface and a circular extractor base having a diameter of 1.41 mm would be considered matched in size for the purpose of this application. Similarly, a group of optical elements arranged randomly to form an extractor will have an irregularly shaped extractor base. In this case, either a lateral dimension or the surface area of the extractor base can be matched in size to the emitting surface. The size of the extractor base can also be made slightly smaller than the size of the emitting surface. This can have advantages if one of the goals is to provide electrical contacts for the LED die or array of LED dies.

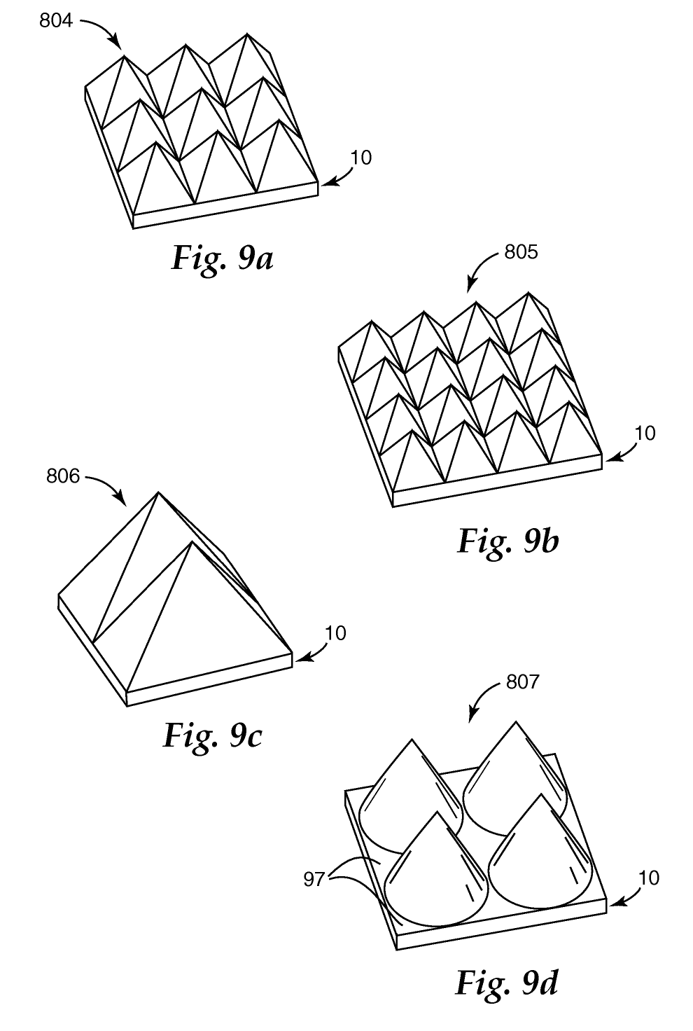

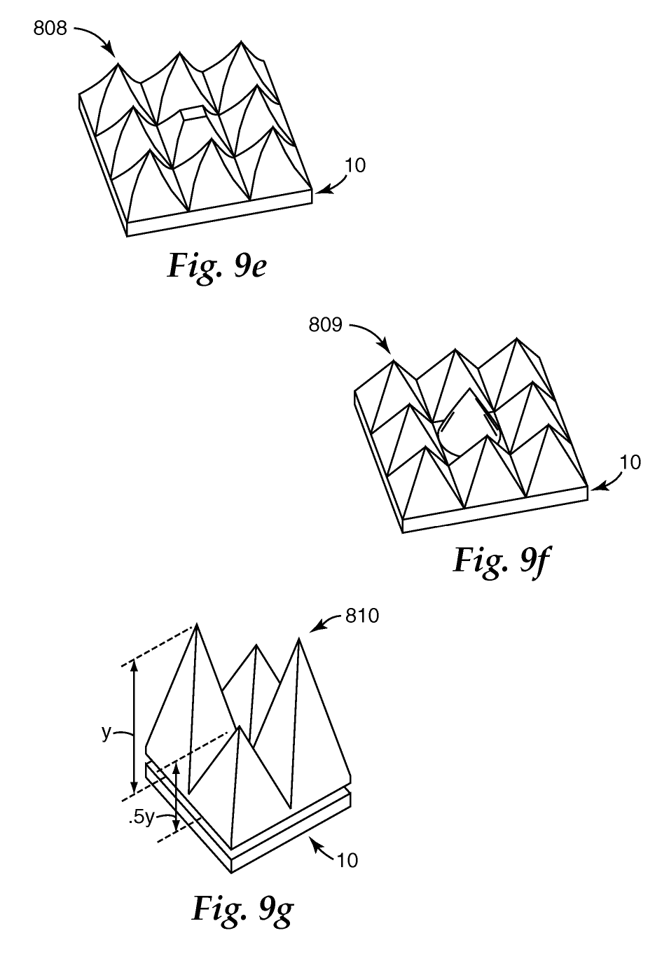

The group of optical elements forming an extractor can include any number of individual optical elements. In some embodiments, the extractor comprises optical elements arranged to provide a side emitting light distribution profile. Preferred side-emitting embodiments include extractors having 2×2, 2×3, and 3×3 arrays of optical elements. Exemplary arrays are depicted in FIGS. 9a-9g. FIG. 9a shows a 3×3 optical element array 804 bonded to an LED die 10. FIG. 9b shows a 4×4 optical element array 805 bonded to an LED die 10. FIG. 9c shows a 1×2 optical element array 806 bonded to an LED die 10. FIG. 9d shows a 2×2 optical element array 807 bonded to an LED die 10. In FIGS. 9a-9c, the optical elements are pyramid-shaped, while in FIG. 9d the optical elements are cone-shaped. The circular bases of the optical elements in array 807 allow portions of the emitting surface of the LED die to be exposed. The open portions 97 of the extractor allow for providing electrical contacts for the LED die 10.

FIG. 9e shows a 3×3 optical element array 808 bonded to an LED die 10 in which the shape of the optical elements is varied. In this embodiment, the optical element in the center of the array, i.e., the optical element of the array in the second row, second column, has a portion near the base that converges toward a blunted apex while the remaining 8 optical elements of the optical element array 808 have converging portions that are concave.

FIG. 9f shows a 2×2 optical element array 809 bonded to an LED die 10 in which the shape of the optical elements is varied. The optical element array 809 comprises a 3×3 array of optical elements in which the optical element in the center of the array, i.e., the optical element of the array in the second row, second column, has a circular shaped base while the remaining 8 optical elements of the optical element array 809 have a square shaped base.

FIG. 9g shows a 2×2 optical element array 810 bonded to an LED die 10 in which the size of the optical elements is varied. The 2×2 optical element array 810 includes optical elements shaped as pyramids in which two of the four pyramidal elements have a ratio of height to side-of-base of y to 1 (y:1) and two other of the four pyramidal elements have a ratio of height to side-of-base of 0.5 y to 1 (0.5 y:1).

Preferably, each of the optical elements forming the extractor has a base that is ≧10 μm in size. The size of the base can be measured as any lateral dimension, including without limitation the width, height, or diameter of the base. For irregularly shaped optical element bases, the size of the base can be the largest, average, or smallest lateral dimension. Optical elements having bases larger than or equal to 10 μm in size are preferred so that diffraction of light is not the dominant mechanism in light propagation.

In some embodiments, only some of the optical elements have bases larger than or equal to 10 μm in size. In those embodiments, it is preferred that at least 80% of the extractor base is occupied by optical elements having bases larger than or equal to 10 μm in size.

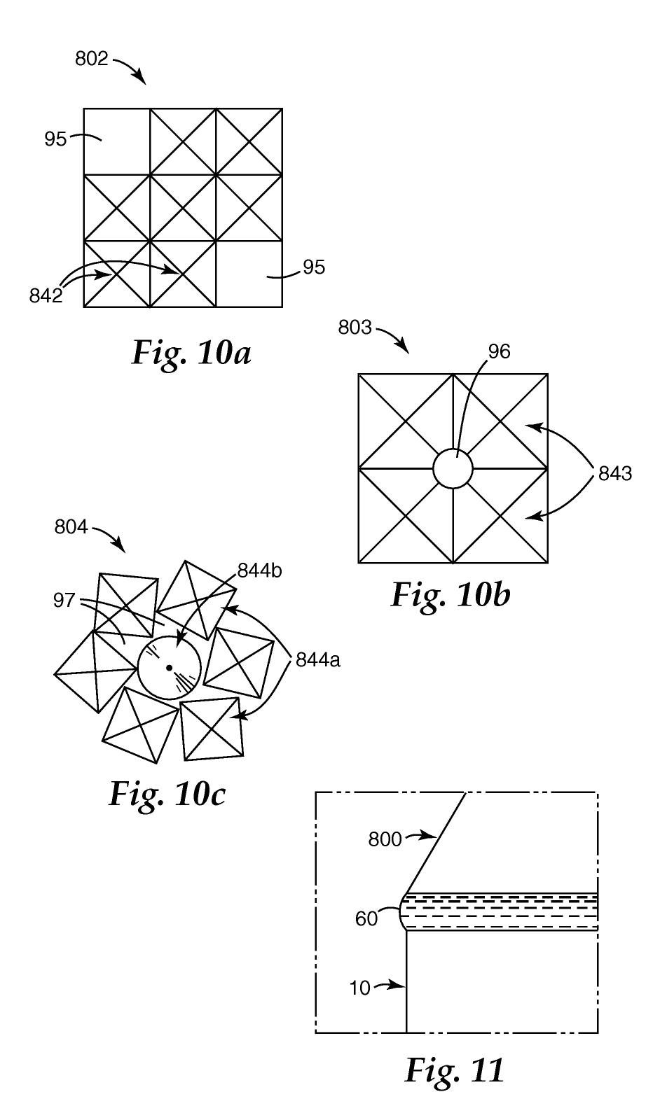

FIG. 10a shows a top view of an extractor 802 having a 3×3 array of optical elements 842. Two of the corner optical elements are removed so that the extractor 802 includes open portions 95, leaving the LED die exposed. FIG. 10b shows a 2×2 optical element array forming the extractor 803. Here, the corners of each optical element 843 are truncated to form an open portion 96 shaped as a circular opening in the center of the extractor 803. FIG. 10c shows a top view of an extractor 804 formed by arranging a group of optical elements 844 randomly. FIG. 10c shows an example of an extractor formed by grouping pyramid-shaped optical elements 844a together with a cone-shaped optical element 844b. Here, the extractor 804 includes open portions 97. The open portions of the extractor can have a variety of shapes as shown, and can also include, without limitation, channels, lines, circles, squares, stars, and the like, or any combination thereof. Extractors having open portions leave portions of the LED die(s) exposed and are useful for providing electrical contacts for the LED die(s).

The optical elements and extractors disclosed herein are made of solid, transparent materials having a relatively high refractive index. Suitable materials for optical elements and extractors include without limitation inorganic materials such as high index glasses (e.g., Schott glass type LASF35 or N-LAF34, available from Schott North America, Inc., Elmsford, N.Y. under trade names LASF35 and N-LAF34, respectively; or high index glass compositions described in commonly owned U.S. patent application Ser. No. 11/381,518 titled LED EXTRACTOR COMPOSED OF HIGH INDEX GLASS (Attorney Docket No. 61216US002)) and ceramics (e.g., sapphire, zinc oxide, zirconia, diamond, and silicon carbide). Sapphire, zinc oxide, diamond, and silicon carbide are particularly useful since these materials also have a relatively high thermal conductivity (0.2-5.0 W/cm K). High index polymers or nanoparticle filled polymers are also contemplated. Suitable polymers can be both thermoplastic and thermosetting polymers. Thermoplastic polymers can include polycarbonate and cyclic olefin copolymer. Thermosetting polymers can be for example acrylics, epoxy, silicones and others known in the art. Suitable ceramic nanoparticles include zirconia, titania, zinc oxide, and zinc sulfide.

The index of refraction of the extractor (nₒ) is preferably similar to the index of the material at the LED die emitting surface (nₑ). Preferably, the difference between the two is no greater than 0.2 (|nₒ−nₑ|≦0.2). Optionally, the difference can be greater than 0.2 depending on the materials used. For example, the emitting surface can have an index of refraction of 1.75. A suitable extractor can have an index of refraction equal to or greater than 1.75 (nₒ≧1.75), including for example nₒ≧1.9, nₒ≧2.1, and nₒ≧2.3. Optionally, nₒ can be lower than nₑ (e.g., nₒ≧1.7). Preferably, the index of refraction of the extractor is matched to the index of refraction of the primary emitting surface. In some embodiments, the indexes of refraction of both the extractor and the emitting surface material can be the same in value (nₒ=nₑ). For example, a sapphire emitting surface having nₑ=1.76 can be matched with a sapphire optical element, or a glass optical element of N-SF4 (available from Schott North America, Inc., Elmsford, N.Y. under a trade name N-SF4) nₒ=1.76. In other embodiments, the index of refraction of the extractor can be higher or lower than the index of refraction of the emitting surface material. When made of high index materials, optical elements increase light extraction from the LED die due to their high refractive index and modify the emission distribution of light due to their shape, thus providing a tailored light emission pattern. Whether made of different materials or the same material, a light source made by optically coupling an LED die and an extractor has an interface formed between the LED die emitting surface and the extractor base.

Throughout this disclosure, the LED die 10 is depicted generically for simplicity, but can include conventional design features as known in the art. For example, the LED die can include distinct p- and n-doped semiconductor layers, buffer layers, substrate layers, and superstrate layers. A simple rectangular LED die arrangement is shown, but other known configurations are also contemplated, e.g., angled side surfaces forming a truncated inverted pyramid LED die shape. Electrical contacts to the LED die are also not shown for simplicity, but can be provided on any of the surfaces of the die as is known. In exemplary embodiments, the LED die has two contacts both disposed at the bottom surface in a “flip chip” design. The present disclosure is not intended to limit the shape of the optical element or the shape of the LED die, but merely provides illustrative examples.

Optionally, an extractor can include a land layer at its base. A land layer can be added after the extractor is formed, or can be formed during the process of making the extractor (e.g., during molding or abrading). In some embodiments, the land layer can be made of the same material as the extractor. In embodiments where two or more optical elements of different materials are used to form the extractor, the land layer can be matched to one of the optical elements. In other embodiments, the land layer can be made of a different material. Preferably, the index of refraction of the land layer is similar to the index of the emitting surface material of the LED die. For example, for an LED die having a SiC emitting surface material (nₑ=2.7), the land layer can be a high index glass such as described in U.S. patent application Ser. No. 11/381,518 titled LED EXTRACTOR COMPOSED OF HIGH INDEX GLASS (Attorney Docket No. 61216US002). The extractor can consist of the same material or a lower index commercially available optical glass (e.g., nₒ≧1.7). In another example, an LED die having a sapphire emitting surface material (nₑ=1.75), the land layer can also be sapphire (nₗ=1.75). The extractor can consist of the same material or a lower index material (e.g., optical glass or organic compounds such as silicones or epoxies).

FIG. 7b shows an extractor having a land layer 90. The height “h” of the land layer is preferably small compared to the height of the individual optical elements. Alternatively the height of the land layer can also be the same size as or larger than the height of the optical elements.

When made of the same material as the optical elements, the height of the land layer has little effect on light extraction efficiency, as described in Example 4. As the number of individual optical elements in the array is increased (e.g., 10×10 array), the light distribution pattern approaches a Lambertian distribution and the power extracted diminishes, as described in Example 5.

The individual optical elements forming the extractor can all be made of the same material or can be a mix of two or more materials. Any shape of converging optical element can be used in such an extractor, including without limitation pyramid, cone, and wedge-shaped optical elements. Some or all of the optical elements can be converging shapes, depending on the design and particular light distribution desired.

An extractor is considered optically coupled to an LED die, when the minimum gap between the extractor and emitting surface of the LED die is no greater than the evanescent wave. Optical coupling can be achieved by placing the LED die and the extractor physically close together. In context of a single optical element, FIG. 1 shows a gap 150 between the emitting surface 100 of the LED die 10 and the base 120 of optical element 20. Typically, the gap 150 is an air gap and is typically very small to promote frustrated total internal reflection. For example, in FIG. 1, the base 120 of the optical element 20 is optically close to the emitting surface 100 of the LED die 10, if the gap 150 is on the order of the wavelength of light in air. Preferably, the thickness of the gap 150 is less than a wavelength of light in air. In LEDs where multiple wavelengths of light are used, the gap 150 is preferably at most the value of the shortest wavelength. The same optical coupling conditions apply to an extractor comprising a plurality of optical elements.

It is preferred that the gap 150 be substantially uniform over the area of contact between the emitting surface 100 and the base 120, and that the emitting surface 100 and the base 120 have a roughness of less than 20 nm, preferably less than 5 nm. In such configurations, a light ray emitted from the LED die 10 outside the escape cone or at an angle that would normally be totally internally reflected at the LED die-air interface will instead be transmitted into the optical element 20. To promote optical coupling, the surface of the base 120 can be shaped to match the emitting surface 100. For example, if the emitting surface 100 of LED die 10 is flat, as shown in FIG. 1, the base 120 of optical element 20 can also be flat. Alternatively, if the emitting surface of the LED die is curved (e.g., slightly concave) the base of the optical element can be shaped to mate with the emitting surface (e.g., slightly convex). The size of the base 120 can be smaller, equal, or larger than LED die emitting surface 100.

Suitable gap sizes include 100 nm, 50 nm, and 25 nm. Preferably, the gap is minimized, such as when the LED die and the base of the extractor are polished to optical flatness and wafer bonded together. The extractor and LED die(s) can be bonded together by applying high temperature and pressure to provide an optically coupled arrangement. Any known wafer bonding technique can be used. The finished light source will have an interface formed between the emitting surface of the LED die(s) and the base of the extractor. Exemplary wafer bonding techniques are described in U.S. Patent Application Pub. No. 2006/0094340, titled PROCESS FOR MANUFACTURING OPTICAL AND SEMICONDUCTOR ELEMENTS (Attorney Docket No. 60203US002).

In case of a finite gap, optical coupling can be achieved or enhanced by adding a thin optically conducting layer between the emitting surface of the LED die and the base of the extractor. FIG. 11 shows a partial schematic side view of an extractor 800 and LED die 10 with a thin optically conducting layer 60 disposed within the gap 150. Like the gap 150, the optically conducting layer 60 can be 100 nm, 50 nm, 25 nm in thickness or less. Preferably, the refractive index of the optically coupling layer is closely matched to the refractive index of the emission surface material or the extractor. An optically conducting layer can be used in both bonded and non-bonded (mechanically decoupled) configurations. In bonded embodiments, the optically conducting layer can be any suitable bonding agent that transmits light, including, for example, a transparent adhesive layer, inorganic thin films, fusable glass frit or other similar bonding agents. Additional examples of bonded configurations are described, for example, in U.S. Pat. No. 7,064,355 titled LIGHT EMITTING DIODES WITH IMPROVED LIGHT EXTRACTION EFFICIENCY (Camras et al.) issued on Jun. 20, 2006.

In non-bonded embodiments, an LED die can be optically coupled to the extractor without use of any adhesives or other bonding agents between the LED die and the extractor. Non-bonded embodiments allow both the LED die and the extractor to be mechanically decoupled thus allowing them to move independently of each other. For example, the extractor can move laterally with respect to the LED die. In another example both the extractor and the LED die are free to expand as each component becomes heated during operation. In such mechanically decoupled systems the majority of stress forces, either sheer or normal, generated by expansion are not transmitted from one component to another component. In other words, movement of one component does not mechanically affect other components. This configuration can be particularly desirable where the light emitting material is fragile, where there is a coefficient of expansion mismatch between the LED die and the extractor, and/or where the LED is being repeatedly turned on and off.

Mechanically decoupled configurations can be made by placing the extractor optically close to the LED die (with only a very small air gap between the two). The air gap should be small enough to promote frustrated total internal reflection, as described above.

Alternatively, as shown in FIG. 11, a thin optically conducting layer 60 (e.g., an index matching fluid) can be added in the gap 150 between the extractor 800 and the LED die 10, provided that the optically conducting layer allows the optical element and LED die to move independently. Examples of materials suitable for the optically conducting layer 60 include index matching oils, and other liquids or gels with similar optical properties. Optionally, optically conducting layer 60 can also be thermally conducting.

The extractor and LED die can be encapsulated together using any of the known encapsulant materials to make a final LED package or light source. Encapsulating the extractor and LED die provides a structure to hold them together and can be particularly suited in the non-bonded embodiments.

An extractor optically coupled to an LED die is effective in extracting light out of the LED die. Applicants found that encapsulating the LED die and the extractor in an encapsulant material can increase the efficiency with which light is extracted out of the LED die. The encapsulating material preferably has an index of refraction that is lower than the index of refraction of the extractor and the LED die. The encapsulant can be of any known shape, including domes, cones, pyramids, and cusped shapes. The shape of the encapsulant can be defined by surface tension of the material from which it is formed or it can be defined by a mold and then cured or hardened to form the desired shape. In some embodiments, the encapsulant can provide an increase in power extracted from the LED die as compared to the power extracted by the extractor alone.

In constructing the light source comprising an encapsulant, the extractor can simply be placed upon the emitting surface of the LED die, and a precursor liquid encapsulating material can be metered out in sufficient quantity to encapsulate the LED die and the extractor, followed by curing the precursor material to form the finished encapsulant. Alternatively, the extractor can be bonded to the emitting surface of the LED die before metering out the precursor liquid encapsulating material. Suitable materials for this purpose include conventional encapsulation formulations such as silicone or epoxy materials. Generally, encapsulants are conformable polymer materials including epoxies, silicones, thermoplastics, acrylics, and thermosets. Preferably, the refractive index of the encapsulant is lower than that of the extractor and the LED die.

Additional details relating to optical elements are described in commonly owned U.S. patent application Ser. No. 11/381,293, titled LED PACKAGE WITH WEDGE-SHAPED OPTICAL ELEMENT (Attorney Docket No. 62044US002), U.S. patent application Ser. No. 11/381,324, titled LED PACKAGE WITH CONVERGING OPTICAL ELEMENT (Attorney Docket No. 62076US002), U.S. patent application Ser. No. 11/381,329, titled LED PACKAGE WITH COMPOUND CONVERGING OPTICAL ELEMENT (Attorney Docket No. 62080US002), U.S. patent application Ser. No. 11/381,332, titled LED PACKAGE WITH ENCAPSULATED CONVERGING OPTICAL ELEMENT (Attorney Docket No. 62081US002), U.S. Patent Application Pub. No. 2006/0091784, titled LED PACKAGE WITH NON-BONDED OPTICAL ELEMENT (Attorney Docket No. 60216US002), and U.S. patent application Ser. No. 11/381,984, titled LED PACKAGE WITH NON-BONDED CONVERGING OPTICAL ELEMENT (Attorney Docket No. 62082US002) which are incorporated herein by reference, to the extent they are not inconsistent with the foregoing disclosure.

Although some of the embodiments described above refer to a single optical element by way of example, the features described in context of those embodiments also apply to embodiments in which an extractor comprises a plurality of optical elements.

### EXAMPLES

The performance of extractors was modeled using “LightTools” software Version 5.2.0 from Optical Research Associates, Pasadena Calif. For each simulation, the following parameters were used:
The LED die Epi-layer is modeled using a 200 nm×1 mm×1 mm, 1 Watt uniform volume source, centered in a 5 micron×1 mm×1 mm GaN layer, which has a refractive index of 2.4 and an optical density of 2.1801.
The bottom surface of the GaN layer specularly reflects 85% and absorbs 15%.
The LED die substrate is sapphire having a dimension of 0.145 mm×1 mm×1 mm, a refractive index of 1.76, and an optical density of 0.0.
The extractors are also sapphire having bases of 1 mm×1 mm and heights as specified in the Examples.
There is no gap between the extractors and the die.

Modeling results are shown in 2 plot types, labeled “a” and “b”. The first type (a) is an intensity contour plot, which is a polar plot where the radius represents polar angle, and the numbers around the perimeter represent the azimuthal angle. The darkness for grey scale plot at a certain position represents the intensity (in units of power per solid angle) at the direction defined by the polar angle and the azimuthal angle. An intensity contour plot can represent light intensity distribution of a hemisphere (usually a polar angle of 0° to 90° and an azimuthal angle of 0° to 360° is chosen).

The second type (b) is an intensity line plot. An intensity line plot is a polar plot where the radius scale represents the intensity (with unit of power per solid angle), and the perimeter scale represents the polar angle. An intensity line plot represents a vertical slice through the light intensity hemisphere of the intensity contour plot. It shows the data of a constant azimuthal angle and the data of this angle +180°. The right part with the perimeter scale from 0° to 180° represents the data of this constant azimuthal angle, and the left part with the perimeter scale from 180° to 360° represents the data of this azimuthal angle +180° It is a more quantitatively readable representation of part of the data shown in the intensity contour plot.

### Example 1

### Bare LED Die (Comparative)

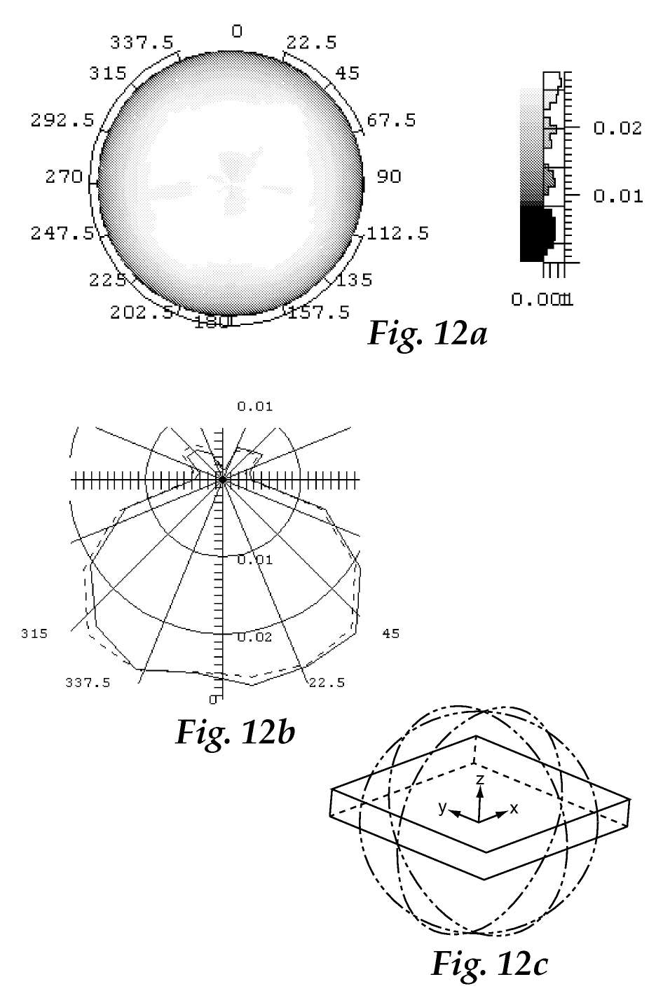

In Example 1, 300,000 rays were traced, using the parameters described above. FIGS. 12a-b show the output of an LED die alone (no extractor). This arrangement is illustrated schematically in FIG. 12c. FIG. 12a shows that the emission is a broad and generally uniform angular distribution across a hemisphere. In FIG. 12b, two intensity line plots are shown. The solid line represents light intensity at 0° (azimuthal angle). The dashed line represents light intensity at 90° (azimuthal angle). FIG. 12b shows that the light intensity is approximately the same at both 0° and at 90°. The net output of this system is 0.1471 W.

### Example 2

### Converging Pyramid

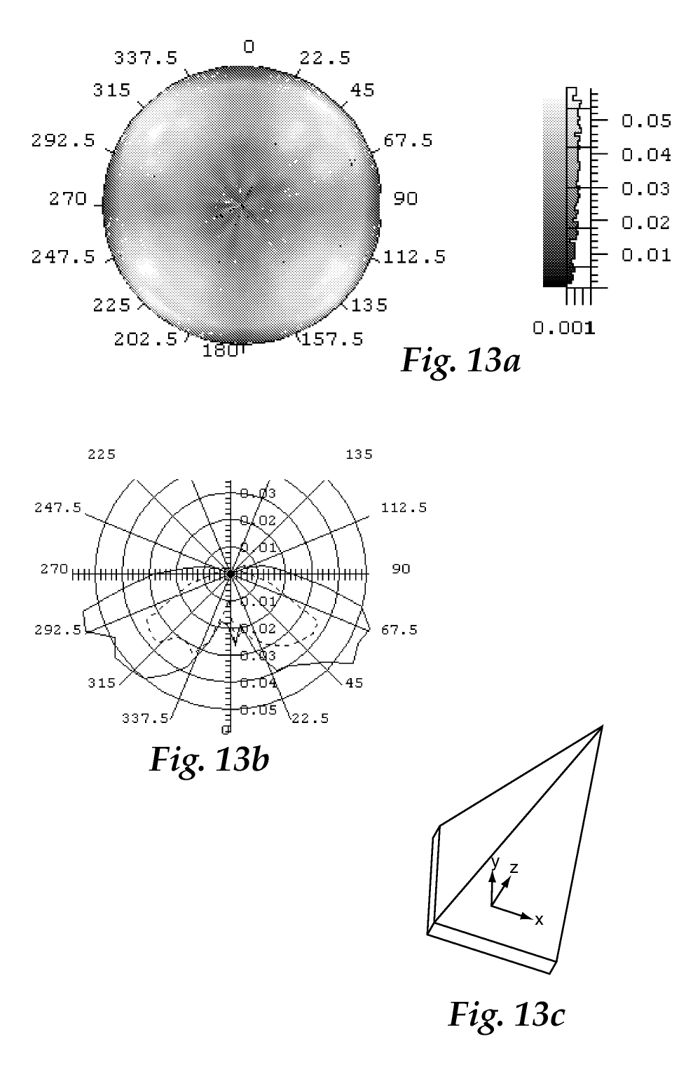

In Example 2, 300,000 rays were traced, using the parameters described above. FIGS. 13a-b show the emission light intensity for the LED die of Example 1 in combination with a symmetrical sapphire extractor of pyramidal shape having a height of 2 mm. This arrangement is illustrated schematically in FIG. 13c. The intensity contour plot in FIG. 13a shows that the emission pattern is primarily concentrated into four lobes. The intensity line plot in FIG. 13b shows the intensity at a 45° azimuthal angle slice (solid line) and a 90° azimuthal slice (dashed line). For the 45° azimuthal angle slice, the light intensity has a maximum at around 53° and is centered at about 50° for the right part of the plot, and has a maximum at 292° and is centered at about 310° for the left side of the plot. For the 90° azimuthal angle slice, the light intensity has a maximum at 50° and is centered at about 40° for the right part of the plot, and has a maximum at 310° and is centered at about 320° for the left side of the plot. The net output of this system is 0.2695 W, compared with 0.1471 W for the LED die alone (Example 1).

### Example 3

### Array of Converging Pyramids

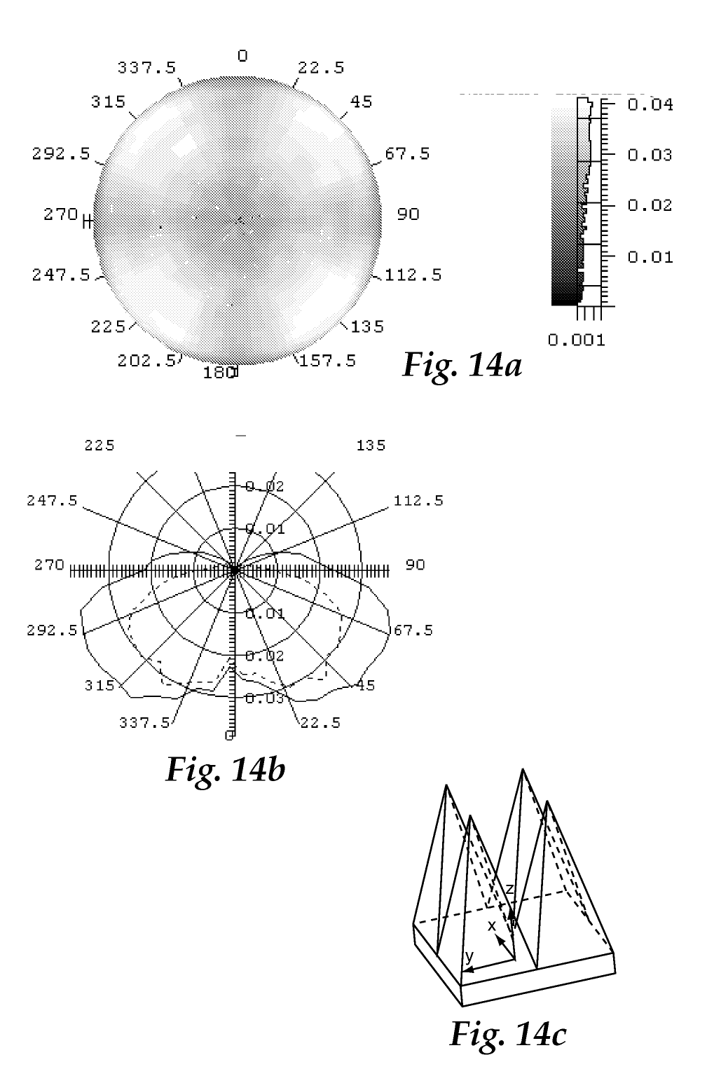

In Example 3, 1,000,000 rays were traced, using the parameters described above. FIGS. 14a-b show the emission light intensity for the LED of Example 1 in combination with a 2×2 array of sapphire optical elements shaped as pyramids. For each optical element, the ratio of height to side of base is 2 to 1, as in the single pyramid of Example 2. The 2×2 array includes a 0.1 micron land layer. This arrangement is illustrated schematically in FIG. 14c. The intensity contour plot in FIG. 14a shows that the emission pattern is primarily concentrated into four lobes having relatively high intensity (bright spots). The lobes in this example are somewhat more spread out than the lobes in Example 2. The intensity line plot in FIG. 14b shows the intensity at a 45° azimuthal angle slice (solid line) and a 90° azimuthal slice (dashed line). For the 45° azimuthal angle slice, the light intensity has a maximum at around 60° and is centered at about 50° for the right part of the plot, and has a maximum at around 300° and is centered at about 310° for the left side of the plot. For the 90° azimuthal angle slice, the light intensity has a maximum at 40° and is centered at about 40° for the right part of the plot, and has a maximum at 325° and is centered at about 320° for the left side of the plot. The net output of this system is 0.2403 W, compared with 0.1471 W for the LED die alone (Example 1) and 0.2695 for the single pyramid extractor (Example 2).

### Example 4

### Effect of Land Layer Height on Extraction Efficiency

In Example 4, 200,000 rays were traced, using the parameters described above. In this example, a 2×2 array of pyramid-shaped optical elements having a land layer was modeled. The base of each array is 1 mm by 1 mm. The aspect ratio for the individual optical elements in each array is 2:1. Each 2×2 array has a four-lobed side emitting distribution similar to that shown in FIG. 14a. The land layer height was varied and the effect of the power extracted was measured, as shown in Table I. The height of the land layer has no significant effect on the power extracted using the 2×2 array extractor.

TABLE I

| Land Layer Height (μm) | Power Extracted (W) |
|---|---|
| 0.1 | 0.2400 |
| 10 | 0.2403 |
| 100 | 0.2399 |
| 200 | 0.2403 |
| 500 | 0.2405 |
| 1000 | 0.2411 |

### Example 5

### Effect of Array Size on Extraction Efficiency

In Example 5, 200,000 rays were traced, using the parameters described above. Table II shows the effect of varying the array size on the power extracted. The base of each array is 1 mm by 1 mm. The aspect ratio for the individual extractors in each array is 2:1. The 2×2 array has a four-lobed side emitting distribution as shown in FIG. 14a. The 3×3 array also has a four-lobed side emitting distribution, but the lobes are less pronounced. The 5×5 array approaches a Lambertian light distribution pattern, as do the 6×6, 7×7 and 8×8 arrays. The power extracted is relatively good for the 3×3 array, compared to the 2×2 array. The power extracted diminishes as the array size becomes larger.

TABLE II

| Array Type | Power Extracted (W) |
|---|---|
| 2 × 2 | 0.2400 |
| 3 × 3 | 0.2318 |
| 4 × 4 | 0.2236 |
| 5 × 5 | 0.2171 |
| 6 × 6 | 0.2123 |
| 7 × 7 | 0.2080 |
| 8 × 8 | 0.2060 |

While the invention is amenable to various modifications and alternative forms, specifics thereof have been shown by way of example in the drawings and the detailed description. It should be understood, however, that the intention is not to limit the invention to the particular embodiments described. On the contrary, the intention is to cover modifications, equivalents, and alternatives falling within the spirit and scope of the invention as defined by the appended claims.

What is claimed is:

1. A light source, comprising:
an LED die having an emitting surface; and
an extractor comprising a plurality of optical elements each having a base, an apex smaller than the base, and a converging side extending between the base and the apex, wherein the extractor has an extractor base no greater in size than the emitting surface, and wherein the extractor base is optically coupled to the emitting surface forming an interface between the extractor and the LED die.

2. The light source of claim 1, wherein the light source emits light in a side emitting pattern, wherein more than 50 percent of the emitted light is emitted at a polar angle greater than or equal to 45°.

3. The light source of claim 2, wherein the side emitting pattern includes a plurality of side lobes.

4. The light source of claim 1, wherein the light source emits light in a side emitting pattern having a maximum intensity at a polar angle greater than or equal to 45°.

5. The light source of claim 4, wherein the side emitting pattern includes a plurality of side lobes.

6. A light source of claim 1, wherein the base of each of the optical elements is greater than or equal to 10 μm in size.

7. The light source of claim 1, wherein the extractor base and the emitting surface are matched in size.

8. The light source of claim 1, wherein the extractor comprises a 2×2 array of pyramidal shaped optical elements, wherein each of the optical elements has an index of refraction no greater than or equal to 1.75, and further wherein the extractor is bonded to the LED die at the emitting surface.

9. The light source of claim 8, further comprising an encapsulant material encapsulating the LED die and the extractor.

10. The light source of claim 8, wherein the extractor includes open portions for providing electrical contacts for the LED die.

11. The light source of claim 1, wherein the extractor comprises a land layer.

12. The light source of claim 1, wherein the extractor is bonded to the LED die at the emitting surface.

13. The light source of claim 1, wherein each of the optical elements has an index of refraction no greater than or equal to 1.75.

14. The light source of claim 1, wherein each of the optical elements comprises inorganic material.

15. The light source of claim 1, wherein the LED die is one of a plurality of LED dies arranged in an array.

16. The light source of claim 1, wherein the extractor includes open portions for providing electrical contacts for the LED die.

17. The light source of claim 1, further comprising an encapsulant material encapsulating the LED die and the extractor.

18. The light source of claim 1, wherein the apex is shaped as one of a point, a line, and a surface.

19. A method of making a light source, comprising the steps of:
providing an LED die having an emitting surface;
forming a plurality of optical elements each having a base, an apex smaller than the base, and a converging side extending between the base and the apex;
arranging the plurality of optical elements to form an extractor having an extractor base no greater in size than the emitting surface; and
optically coupling the extractor base to the emitting surface of the LED die.

20. The method of claim 19, wherein the forming step includes molding the optical elements.

21. The method of claim 20, wherein the arranging step includes leaving portions of the extractor open for providing electrical contacts for the LED die.

22. The method of claim 21, wherein the forming and arranging steps are performed simultaneously.

23. The method of claim 22, wherein the optically coupling step includes bonding the extractor base to the emitting surface of the LED die.

24. The method of claim 23, further comprising a step of encapsulating the LED die and the extractor with an encapsulant material.

25. The method of claim 19, wherein the arranging step includes leaving portions of the extractor open for providing electrical contacts for the LED die.

26. The method of claim 19, wherein the optically coupling step includes bonding the extractor base to the emitting surface of the LED die.

27. The method of claim 19, further comprising a step of encapsulating the LED die and the extractor with an encapsulant material.

28. A light source, comprising:
an LED die having an emitting surface;
an extractor comprising a plurality of optical elements each having a base, an apex smaller than the base, and a converging side extending between the base and the apex; and
an encapsulant material encapsulating the LED die and the extractor, wherein the extractor includes open portions for providing electrical contacts for the LED die,
wherein the extractor has an extractor base no greater in size than the emitting surface, wherein the extractor base is optically coupled to the emitting surface forming an interface between the extractor and the LED die, and wherein the extractor is bonded to the LED die at the emitting surface wherein the light source emits light in a side emitting pattern, and further wherein more than 50 percent of the emitted light is emitted at a polar angle greater than or equal to 45°.
